(19) United States
(12) Patent Application Publication
(10) Pub. No.: US 2024/0324367 A1
(43) Pub. Date: Sep. 26, 2024

(54) DISPLAY DEVICE

(71) Applicant: Samsung Display Co., LTD., Yongin-si (KR)

(72) Inventors: Junhyun PARK, Yongin-si (KR); Mukyung JEON, Yongin-si (KR)

(21) Appl. No.: 18/613,027

(22) Filed: Mar. 21, 2024

(30) Foreign Application Priority Data
Mar. 24, 2023 (KR) 10-2023-0039091
Jun. 22, 2023 (KR) 10-2023-0080678

(51) Int. Cl. H10K 59/131; H10K 59/121

(52) U.S. Cl. CPC H10K 59/131; H10K 59/1213; H10K 59/1216

(57) ABSTRACT

A display device includes first and second subpixel circuits disposed adjacent to each other in a first direction and each including a driving transistor and a first capacitor, a first horizontal voltage line extending in the first direction and electrically connected to a semiconductor layer of a first transistor electrically connected to the driving transistor of the first subpixel circuit, a second horizontal voltage line extending in the first direction and electrically connected to a semiconductor layer of a second transistor electrically connected to the driving transistor of the second subpixel circuit electrically connected to a transistor, and a first signal line extending in the first direction and electrically connected to a gate electrode of the first transistor and a gate electrode of the second transistor, wherein the first horizontal voltage line and the second horizontal voltage line are disposed on different layers.

This application claims priority to Korean Patent Application No. 10-2023-0039091, filed on Mar. 24, 2023 and Korean Patent Application No. 10-2023-0080678, filed Jun. 22, 2023, and all the benefits accruing therefrom under 35 U.S.C. § 119, the contents of which in their entirety are herein incorporated by reference.

### BACKGROUND

### 1. Field

One or more embodiments relate to a display device, and more particularly a display device that may be driven at a high rate without a decrease in resolution.

### 2. Description of the Related Art

Recently, display devices have been used for various purposes. In addition, due to the wide range of use of display devices, there have been increasing demands for high-resolution display devices. Various types of processes may be performed to manufacture high-resolution display devices.

### SUMMARY

One or more embodiments include a structure of a display device.

According to one or more embodiments, a display device includes a first subpixel circuit and a second subpixel circuit being disposed adjacent to each other in a first direction, the first subpixel circuit and the second subpixel circuit each including a driving transistor and a first capacitor, a first light-emitting diode electrically connected to the first subpixel circuit, a second light-emitting diode electrically connected to the second subpixel circuit, a first horizontal voltage line extending in the first direction and electrically connected to a semiconductor layer of a first transistor electrically connected to the driving transistor of the first subpixel circuit, a second horizontal voltage line extending in the first direction and electrically connected to a semiconductor layer of a second transistor electrically connected to the driving transistor of the second subpixel circuit, and a first signal line extending in the first direction and electrically connected to a gate electrode of the first transistor of the first subpixel circuit and a gate electrode of the second transistor of the second subpixel circuit, wherein the first horizontal voltage line and the second horizontal voltage line are respectively disposed on different layers.

In an embodiment, the display device may further include an insulating layer interposed between the first horizontal voltage line and the second horizontal voltage line, wherein the first horizontal voltage line may be disposed under the insulating layer and the second horizontal voltage line may be disposed on the insulating layer.

In an embodiment, each of the first subpixel circuit and the second subpixel circuit may further include a second capacitor, wherein the first capacitor may include a first lower electrode disposed on a same layer as a gate electrode of the driving transistor and a first upper electrode disposed over the first lower electrode, the second capacitor may include a second lower electrode disposed on a same layer as the first upper electrode and a second upper electrode disposed over the second lower electrode, and the first horizontal voltage line may be disposed on a same layer as the second upper electrode.

In an embodiment, the second lower electrode of the second capacitor may be disposed on a same layer as the first upper electrode of the first capacitor, and the first lower electrode of the first capacitor may be disposed on a same layer as the gate electrode of the driving transistor.

In an embodiment, the first horizontal voltage line may be electrically connected to the semiconductor layer of the first transistor through a bridge electrode.

In an embodiment, the bridge electrode may be disposed on a same layer as the second horizontal voltage line.

In an embodiment, the first signal line may include a first sub-signal line and a second sub-signal line disposed on the first sub-signal line and electrically connected to the first sub-signal line,
wherein the second sub-signal line may be disposed on a same layer as the second horizontal voltage line, and wherein the first sub-signal line may include each of the gate electrode of the first transistor of the first subpixel circuit and the gate electrode of the second transistor of the second subpixel circuit.

In an embodiment, the first transistor of the first subpixel circuit may electrically connect the first horizontal voltage line to a subpixel electrode of the first light-emitting diode, in response to a signal from the first signal line, and the second transistor of the second subpixel circuit may electrically connect the second horizontal voltage line to a subpixel electrode of the second light-emitting diode, in response to a signal from the first signal line.

In an embodiment, the display device may further include a plurality of vertical voltage lines extending in a second direction crossing the first direction, wherein the plurality of vertical voltage lines may be spaced apart from one another and a plurality of subpixel circuits may be arranged between two adjacent vertical voltage lines.

In an embodiment, the display device may further include a third horizontal voltage line extending in the first direction, wherein a portion of any one of the plurality of vertical voltage lines may include a first pattern portion having a width greater than a width of another portion and may be electrically connected to the third horizontal voltage line through a contact hole which is disposed directly under the first pattern portion, and a portion of another one of the plurality of vertical voltage lines may include a second pattern portion having a width greater than a width of another portion and a contact hole may not be located directly under the second pattern portion, wherein the first horizontal voltage line and the second horizontal voltage line may be disposed adjacent to each other, and wherein, with reference to a virtual line extending in the second direction to cross the first capacitor in a plan view, the third horizontal voltage line may be disposed opposite to the first horizontal voltage line and the second horizontal voltage line.

According to one or more embodiments, a display device includes a first subpixel circuit and a second subpixel circuit being disposed adjacent to each other in a first direction, the first subpixel circuit and the second subpixel circuit each including a driving transistor and a first capacitor, a first light-emitting diode electrically connected to the first subpixel circuit, a second light-emitting diode electrically connected to the second subpixel circuit, a first horizontal voltage line extending in the first direction and electrically connected to a semiconductor layer of a first transistor electrically connected to the driving transistor of the first subpixel circuit, a first vertical voltage line extending in a second direction crossing the first direction and electrically connected to the first horizontal voltage line, a second horizontal voltage line extending in the first direction and electrically connected to a semiconductor layer of a second transistor electrically connected to the driving transistor of the second subpixel circuit, a second vertical voltage line extending in the second direction and electrically connected to the second horizontal voltage line, and a first signal line extending in the first direction and electrically connected to a gate electrode of the first transistor of the first subpixel circuit and a gate electrode of the second transistor of the second subpixel circuit.

In an embodiment, a plurality of subpixel circuits may be arranged between the first vertical voltage line and the second vertical voltage line.

In an embodiment, the display device may further include a third horizontal voltage line extending in the first direction and a third vertical voltage line extending in the second direction, wherein a portion of the third vertical voltage line may include a first pattern portion having a width greater than a width of another portion and wherein the third vertical voltage line may be electrically connected to the third horizontal voltage line through a contact hole which is disposed directly under the first pattern portion, and a portion of at least one selected from between the first vertical voltage line and the second vertical voltage line may include a second patter portion having a width greater than a width of another portion and a contact hole which may not be located directly under the second pattern portion.

In an embodiment, each of the first subpixel circuit and the second subpixel circuit may further include a second capacitor, wherein the first capacitor may include a first lower electrode disposed on a same layer as a gate electrode of the driving transistor and a first upper electrode disposed over the first lower electrode, wherein the second capacitor may include a second lower electrode arranged on a same layer as the first upper electrode and a second upper electrode disposed over the second lower electrode, and the first horizontal voltage line may be disposed on a same layer as the second upper electrode and the second horizontal voltage line may disposed on a layer different from a layer on which the first horizontal voltage line is disposed.

In an embodiment, the first horizontal voltage line may be electrically connected to a semiconductor layer of the first transistor through a bridge electrode.

In an embodiment, the bridge electrode may be disposed on a same layer as the second horizontal voltage line.

In an embodiment, the first signal line may include a first sub-signal line and a second sub-signal line disposed on the first sub-signal line and electrically connected to the first sub-signal line, wherein the second sub-signal line is disposed on a same layer as the second horizontal voltage line, and wherein the first sub-signal line may include each of the gate electrode of the first transistor of the first subpixel circuit and the gate electrode of the second transistor of the second subpixel circuit.

### BRIEF DESCRIPTION OF THE DRAWINGS

The above and other aspects, features, and advantages of certain embodiments of the invention will be more apparent from the following description taken in conjunction with the accompanying drawings, in which:

FIG. 1 is a top-plan view of a display device, according to an embodiment;

FIG. 2 is a top-plan view, schematically illustrating a display device, according to an embodiment;

FIG. 3 is an equivalent circuit schematic diagram of any one pixel arranged in a display device, according to an embodiment;

FIG. 4 is a cross-sectional view schematically illustrating a display device, according to an embodiment;

FIG. 5 is a top-plan view schematically illustrating wirings as arranged in a display area of a display device, according to an embodiment;

FIG. 6 is a top-plan view schematically illustrating some transistors arranged in a display area of a display device and conductive lines electrically connected to the transistors, according to an embodiment;

FIG. 7 is a cross-sectional view of a display device which illustrates a cross-section taken along a line VIIa-VIIa′ and a cross-section taken along a line VIIb-VIIb′ shown in FIG. 6, according to an embodiment;

FIG. 8 is a cross-sectional view of a display device, illustrating a cross-section taken along a line VIII-VIII′ shown in FIG. 6, according to an embodiment;

FIG. 9 is a cross-sectional view of a display device illustrating a cross-section taken along a line IX-IX′ shown in FIG. 6, according to an embodiment; and

FIG. 10 is a top-plan view schematically illustrating wirings as arranged in a display area of a display device, according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any variation thereof.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

As used herein, the singular forms are intended to encompass the plural forms as well, unless the context clearly indicates otherwise.

It will be further understood that the terms “comprise,” “comprising,” “include,” “including,” “have,” “having,” and the like, when used herein, specify the presence of stated features and/or elements, but do not preclude the presence and/or addition of one or more other features and/or elements.

In the following embodiments, when a portion such as a film, an area, or a component is on or above another portion, the portion may be directly on the other portion, or other films, areas, and/or components may be located therebetween.

In the drawings, the sizes of elements may be exaggerated or reduced for convenience of description. For example, since the size and thickness of each element is arbitrarily shown in the drawings for convenience of description, the invention is not necessarily limited to those illustrated.

While some embodiments may be differently implemented, a particular process sequence may be performed differently from a sequence described. For example, two processes described in succession may be performed substantially simultaneously, or may be performed in an order opposite to an order described.

In the specification, when it is referred that a film, an area, and a component are connected to another film, area, and/or component, the film, area, and/or component may be directly connected to the other film, area, and/or component, and/or may be indirectly connected with another film, area, and/or component therebetween. For example, when it is referred that a film, an area, and/or a component are electrically connected to another film, area, and/or component, the film, area, and/or component may be directly in electric connection with the other film, area, and/or component, and/or may be indirectly in electric connection with the other film, area, and/or component with another film, area, and/or component therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims

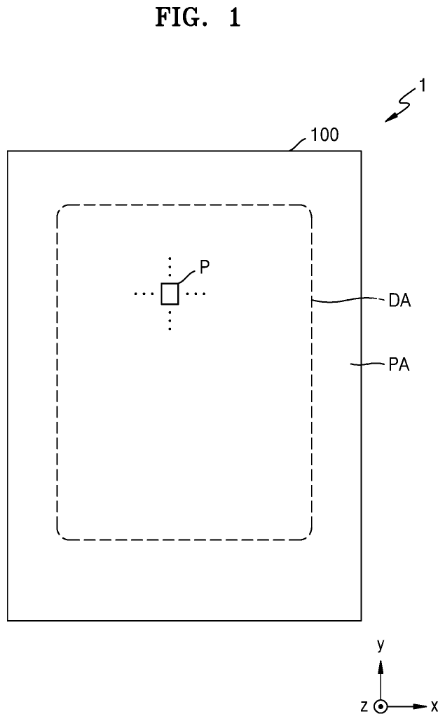

FIG. 1 is a top-plan view of a display device 1, according to an embodiment.

In an embodiment and referring to FIG. 1, the display device 1 includes a display area DA configured to display images and a peripheral area PA arranged around the display area DA. The display device 1 may be configured to provide images to outside using light emitted from the display area DA. As the display device 1 includes a substrate 100, it may also be referred to that the substrate 100 includes the display area DA and the peripheral area PA.

In an embodiment, the substrate 100 may include various materials such as glass, metal, and/or plastic. According to an embodiment, the substrate 100 may include a flexible material. Here, the flexible material may indicate a material that is easily curved, bent, folded, and/or rolled. The substrate 100 including such flexible materials may include ultra-thin glass, metal, and/or plastic.

In an embodiment, subpixels P including various display elements such as organic light-emitting diode OLED may be arranged in the display area DA of the substrate 100. The light-emitting diode may include an organic light-emitting diode including an organic emission layer. Alternatively, the light-emitting diode may include an inorganic light-emitting diode including an inorganic emission layer. A size of the light-emitting diode may be in a range of microscale or nanoscale. For example, the light-emitting diode may include a micro light-emitting diode. Alternatively, the light-emitting diode may include a nanorod light-emitting diode. The nanorod light-emitting diode may include gallium nitride (GaN). In an embodiment, a color conversion layer may be disposed on the nanorod light-emitting diode. The color conversion layer may include quantum dots. Alternatively, the light-emitting diode may include a quantum-dot light-emitting diode including a quantum-dot emission layer. The subpixels P may be arranged in various forms such as a stripe arrangement, a Pentile arrangement, a mosaic arrangement, and the like to implement images.

Although FIG. 1 illustrates an embodiment where a shape of a plane surface of the display area DA is rectangular, in other embodiments, the display area DA may be provided in a polygon shape such as a triangle, a pentagon, or a hexagon, a round shape, an oval shape, an amorphous shape, and the like.

In an embodiment, the peripheral area PA of the substrate 100, which is the area arranged around the display area DA, may include an area in which images are not displayed. Pads to which various wirings configured to deliver electrical signals to be applied to the display area DA, a printed circuit board, and a driver IC chip are attached and may be located in the peripheral area PA.

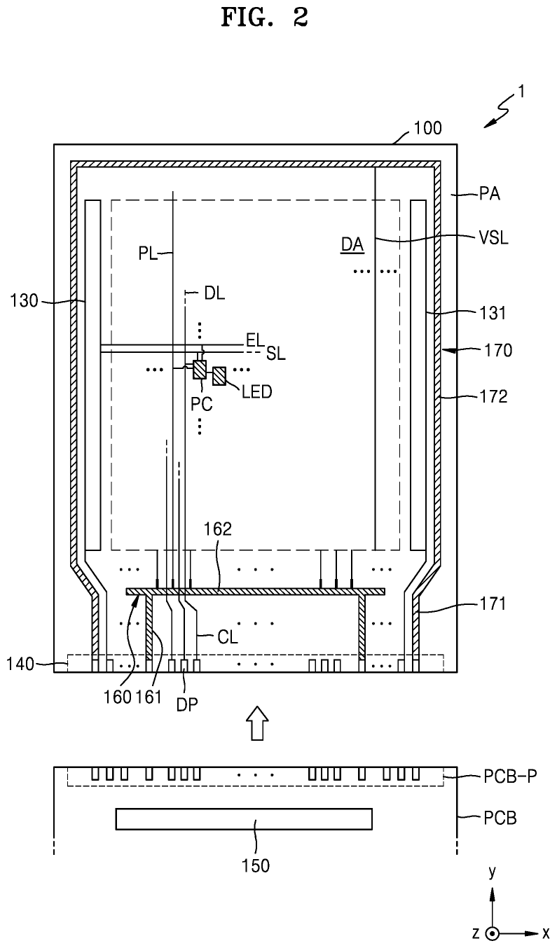

FIG. 2 is a top-plan view schematically illustrating the display device 1, according to an embodiment.

In an embodiment and referring to FIG. 2, the display device 1 may include light-emitting diodes LED arranged in the display area DA and subpixel circuits PC respectively connected to the light-emitting diodes LED. The light-emitting diodes LED and the subpixel circuits PC may be arranged in a first direction (e.g., a ±x direction) and a second direction (e.g., a ±y direction) in the display area DA. The subpixel circuits PC may be electrically connected to scan lines SL, emission control lines EL, data lines DL, and driving voltage lines PL arranged in the display area DA.

In an embodiment, the scan lines SL and the emission control lines EL may respectively extend in the first direction (e.g., the ±x direction) and be electrically connected to the subpixel circuits PC in a same row. The data lines DL and the driving voltage lines PL may respectively extend in the second direction (e.g., the ±y direction) and may be electrically connected to the subpixel circuits PC in a same column.

In an embodiment, a display panel may include a first gate driving circuit 130, a second gate driving circuit 131, a first voltage supply wiring 160, a second voltage supply wiring 170, and a pad portion 140 arranged in the peripheral area PA.

In an embodiment, the first gate driving circuit 130 and/or the second gate driving circuit 131 may each include a scan driving circuit and an emission control driving circuit. The scan driving circuit may be configured to provide a scan signal to each of the subpixel circuits PC through the scan line SL. The emission control driving circuit may be configured to provide an emission control signal to each of the subpixel circuits PC through the emission control line EL.

In an embodiment, the second gate driving circuit 131 may be arranged in parallel to the first gate driving circuit 130 with the display area DA therebetween. Some of the subpixel circuits PC arranged in the display area DA may be electrically connected to the first gate driving circuit 130, and others of the subpixel circuits PC may be connected to the second gate driving circuit 131. In another example, the second gate driving circuit 131 may be omitted.

In an embodiment, the first voltage supply wiring 160 and the second voltage supply wiring 170 may be arranged in the peripheral area PA. The first voltage supply wiring 160 may include a first sub wiring 161 extending in the second direction (e.g., the ±y direction) toward an end portion of the substrate 100 and a second sub wiring 162 extending in parallel to a first side of the display area DA. The second voltage supply wiring 170 may have a loop shape in which a side thereof is open, and may partially surround the display area DA. The second voltage supply wiring 170 may include a first sub wiring 171 extending in the second direction (e.g., the ±y direction) toward the end portion of the substrate 100 and a second sub wiring 172 extending along a second side, a third side, and a fourth side of the display area DA.

In an embodiment, the pad portion 140 may be arranged at a side of the peripheral area PA. The pad portion 140 may include a plurality of pads such as a data pad DP. The pad portion 140 may be exposed without being covered by an insulating layer and may be electrically connected to a printed circuit board PCB. The pads of the pad portion 140 may be electrically connected to a terminal portion PCB-P of the printed circuit board PCB. The printed circuit board PCB may be configured to deliver a signal or a voltage of a controller (not shown) to the display panel.

In an embodiment, a control signal generated in the controller may be delivered to the first gate driving circuit 130 and the second gate driving circuit 131 through the printed circuit board PCB and the pad portion 140.

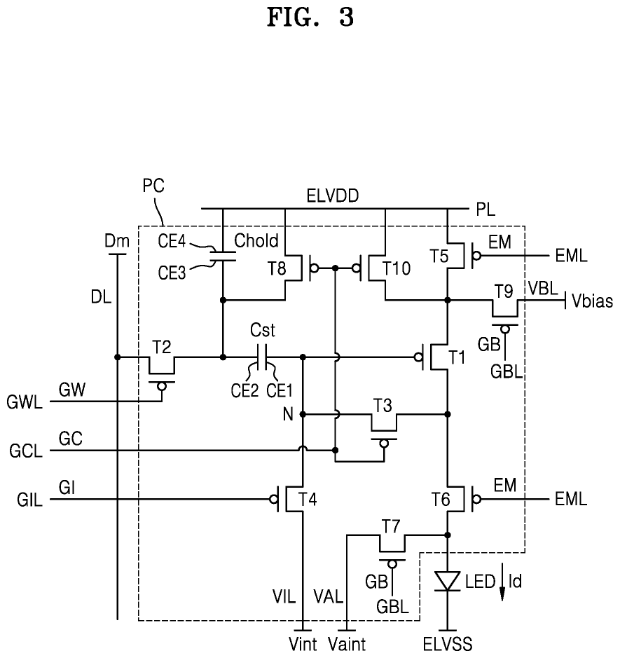

In an embodiment, a driving voltage ELVDD (see FIG. 3) generated in the controller may be delivered to the first voltage supply wiring 160 through the first sub wiring 161 connected to a pad of the pad portion 140. The driving voltage ELVDD may be provided to each of the subpixel circuits PC through the driving voltage line PL connected to the first voltage supply wiring 160.

In an embodiment, a common voltage ELVSS (see FIG. 3) generated in the controller may be delivered to the second voltage supply wiring 170 through the first sub wiring 171 connected to a pad of the pad portion 140. The common voltage ELVSS may be provided to a cathode (or a second electrode) of the light-emitting diode LED that is connected to the second voltage supply wiring 170. Common voltage lines VSL electrically connected to the second voltage supply wiring 170 may be arranged in the display area DA. The common voltage lines VSL may be configured to prevent voltage drop of a second driving voltage that may occur according to the increase in a range of the display area DA.

In an embodiment, a data driving circuit 150 may be electrically connected to the data lines DL. A data signal (or a data voltage) of the data driving circuit 150 may be provided to each of the subpixel circuits PC through a connection line CL connected to the data pad DP of the pad portion 140 and/or a data line DL connected to the connection line CL.

Although FIG. 2 illustrates an embodiment where the data driving circuit 150 is arranged on the printed circuit board PCB, in another embodiment, the data driving circuit 150 may be arranged on the substrate 100. For example, the data driving circuit 150 may be arranged between the pad portion 140 and the first voltage supply wiring 160.

FIG. 3 is an equivalent circuit schematic diagram of any one subpixel circuit PC arranged in the display device 1 (see FIG. 2), according to an embodiment.

In an embodiment and referring to FIG. 3, the subpixel circuit PC electrically connected to the light-emitting diode LED may include transistors and capacitors. The light-emitting diode LED may include a subpixel electrode (e.g., an anode), a counter electrode (e.g., a cathode), and an intermediate layer arranged between the subpixel electrode and the counter electrode and including an emission layer. The subpixel electrode of the light-emitting diode LED may be electrically connected to the subpixel circuit PC, and the counter electrode may be electrically connected to the second voltage supply wiring 170 (see FIG. 2) and/or the common voltage line VSL (see FIG. 2) configured to provide the common voltage ELVSS.

For example, in an embodiment, the subpixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a tenth transistor T10, a first capacitor Cst, and a second capacitor Chold.

In an embodiment, the subpixel circuit PC may be electrically connected to a first scan line GWL, a second scan line GCL, a third scan line GIL, and a fourth scan line GBL respectively configured to deliver a first scan signal GW, a second scan signal GC, a third scan signal GI, and a fourth scan signal GB. The subpixel circuit PC may also be electrically connected to a data line DL configured to deliver a data voltage Dm, an emission control line EML configured to deliver an emission control signal EM, a driving voltage line PL configured to deliver the driving voltage ELVDD, a first voltage line VIL configured to deliver a first initialization voltage Vint, a second voltage line VAL configured to deliver a second initialization voltage Vaint, and a third voltage line VBL configured to deliver a bias voltage Vbias. The emission control line EML in FIG. 3 may correspond to the emission control line EL in FIG. 2.

In an embodiment, the first transistor T1 may include a driving transistor in which a magnitude of a drain current is determined according to a gate-source voltage, and the second transistor T2 to the tenth transistor T10 may each include a switching transistor turned on/off in response to the gate-source voltage, i.e., substantially, a gate voltage. The first transistor T1 to the tenth transistor T10 may each include a thin-film transistor.

In an embodiment, the first capacitor Cst and the second capacitor Chold may be electrically connected to the driving voltage line PL and a gate electrode of the first transistor T1. The first capacitor Cst, which is a storage capacitor, may include a first lower electrode CE1 electrically connected to the gate electrode of the first transistor T1 and a first upper electrode CE2 overlapping the first lower electrode CE1. The second capacitor Chold may include a second lower electrode CE3 electrically connected to the first upper electrode CE2 of the first capacitor Cst and a second upper electrode CE4 connected to the driving voltage line PL.

In an embodiment, the first transistor T1 may be configured to control a magnitude of a driving current Id flowing from the driving voltage line PL to the light-emitting diode LED in response to the gate-source voltage. The first transistor T1 may have a gate electrode connected to the first lower electrode CE1 of the first capacitor Cst, a source electrode connected to the driving voltage line PL through the fifth transistor T5, and a drain electrode connected to the light-emitting diode LED through the sixth transistor T6. The second transistor T2 may electrically connect the data line DL to the first upper electrode CE2 of the first capacitor Cst (or the second lower electrode CE3 of the second capacitor Chold) in response to the first scan signal GW. The second transistor T2 may be configured to deliver the data voltage Dm to the first upper electrode CE2 of the first capacitor Cst (or the second lower electrode CE3 of the second capacitor Chold) in response to the first scan signal GW.

In an embodiment, the third transistor T3 may electrically connect the drain electrode and the gate electrode of the first transistor T1 in response to the second scan signal GC. The third transistor T3 may be connected in series between the drain electrode and the gate electrode of the first transistor T1.

In an embodiment, the fourth transistor T4 may electrically connect the first voltage line VIL to the gate electrode of the first transistor T1 in response to the third scan signal GI. The fourth transistor T4 may be configured to apply the first initialization voltage Vint to the gate electrode of the first transistor T1 in response to the third scan signal GI.

In an embodiment, the fifth transistor T5 may electrically connect the driving voltage line PL to the source electrode of the first transistor T1 in response to the emission control signal EM.

In an embodiment, the sixth transistor T6 may connect the drain electrode of the first transistor T1 to the subpixel electrode (e.g., the anode) of the light-emitting diode LED in response to the emission control signal EM. The sixth transistor T6 may connect the drain electrode of the first transistor T1 and the subpixel electrode (e.g., the anode) of the light-emitting diode LED in response to the emission control signal EM.

Although FIG. 3 illustrates an embodiment where the fifth transistor T5 and the sixth transistor T6 are configured to operate in response to a same emission control signal EM, in another embodiment, the fifth transistor T5 and the sixth transistor T6 may be respectively configured to operate in response to different emission control signals. For example, the fifth transistor T5 may have a gate electrode connected to a first emission control line, and may electrically connect the driving voltage line PL to the source electrode of the first transistor T1 in response to a first emission control signal. The sixth transistor T6 may have a gate electrode connected to a second emission control line, and may electrically connect the drain electrode of the first transistor T1 to the subpixel circuit (e.g., the anode) of the light-emitting diode LED in response to a second emission control signal.

In an embodiment, the seventh transistor T7 may electrically connect the second voltage line VAL to the subpixel electrode (e.g., the anode) of the light-emitting diode LED in response to the fourth scan signal GB. The seventh transistor T7 may be configured to apply the second initialization voltage Vaint to the subpixel electrode (e.g. the anode) of the light-emitting diode LED in response to the fourth scan signal GB. The seventh transistor T7 may include an initialization transistor configured to initialize the subpixel electrode (e.g., the anode) of the light-emitting diode LED.

In an embodiment, the eighth transistor T8 may electrically connect the driving voltage line PL to the first upper electrode CE2 of the first capacitor Cst or the second lower electrode CE3 of the second capacitor Chold in response to the second scan signal GC. The eighth transistor T8 may be configured to apply the driving voltage ELVDD to the first upper electrode CE2 of the first capacitor Cst or the second lower electrode CE3 of the second capacitor Chold in response to the second scan signal GC.

In an embodiment, the ninth transistor T9 may connect the third voltage line VBL to the source electrode of the first transistor T1 in response to the fourth scan signal GB. The ninth transistor T9 may be configured to apply the bias voltage Vbias to the source electrode of the first transistor T1 in response to the fourth scan signal GB.

In an embodiment, the tenth transistor T10 may electrically connect the driving voltage line PL and a drain electrode of the fifth transistor T5 in response to the second scan signal GC.

Although FIG. 3 illustrates an embodiment where the seventh transistor T7 and the ninth transistor T9 are configured to operate in response to a same signal, i.e., the fourth scan signal GB, in another embodiment, the seventh transistor T7 and the ninth transistor T9 may be respectively configured to operate in response to different scan signals.

In an embodiment, the second scan signal GC may be substantially synchronized with the first scan signal GW. The third scan signal GI may be substantially synchronized with the first scan signal GW in a previous column. The fourth scan signal GB may be substantially synchronized with the first scan signal GW. According to another embodiment, the fourth scan signal GB may be substantially synchronized with the first scan signal GW of a next column or the third scan signal GI of a next column.

In an embodiment, the first transistor T1 to the tenth transistor T10 may each include a semiconductor layer including silicon. For example, the first transistor T1 to the tenth transistor T10 may each include a semiconductor layer including low-temperature polysilicon (LTPS). A polysilicon material, which has a high electron mobility (about 100 cm²/Vs or greater), has lower energy consumption and high reliability.

As another example, in an embodiment, the semiconductor layers of the first transistor T1 to the tenth transistor T10 may include oxides of at least one material selected from a group including indium (In), gallium (Ga), stanium (Sn), zirconium (Zr), vanadium (V), hafnium (Hf), cadmium (Cd), germanium (Ge), chronium (Cr), titanium (Ti), aluminum (AI), cesium (Cs), cerium (Ce), and zinc (Zn). For example, the semiconductor layers may include an InSnZnO (ITZO) semiconductor layer, an InGaZnO (IGZO) semiconductor layer, and the like.

As another example, in an embodiment, some of the semiconductor layers of the first transistor T1 to the tenth transistor T10 may include LTPS, and others of the semiconductor layers of the first transistor T1 to the tenth transistor T10 may include an oxide semiconductor (IGZO and the like).

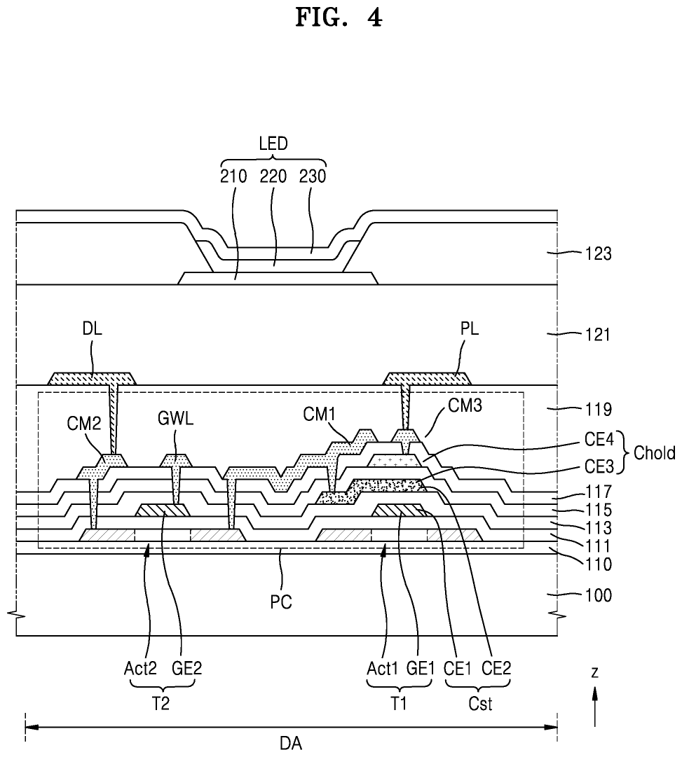

FIG. 4 is a cross-sectional view schematically illustrating the display device 1 (see FIG. 2), according to an embodiment. FIG. 4 illustrates the first transistor T1, the second transistor T2 from among the transistors included in the subpixel circuit PC (see FIG. 3), the first capacitor Cst, and the second capacitor Chold.

In an embodiment, the first transistor T1 may include a first semiconductor layer Act1 and a first gate electrode GE1 at least partially overlapping the first semiconductor layer Act1. The second transistor T2 may include a second semiconductor layer Act2 and a second gate electrode GE2 at least partially overlapping the second semiconductor layer Act2.

In an embodiment, the first semiconductor layer Act1 and the second semiconductor layer Act2 may be disposed on a buffer layer 110. The buffer layer 110 may include a single layer or multiple layers including an inorganic insulating material such as silicon nitride, silicon oxide, and/or silicon oxynitride.

In an embodiment, the first semiconductor layer Act1 and the second semiconductor layer Act2 may each include amorphous silicon or polysilicon. Each of the first semiconductor layer Act1 and the second semiconductor layer Act2 may include a channel area, and may further include a source area and a drain area as impurity doping areas arranged at two sides of the channel area. The source area and the drain area may correspond to the source electrode and the drain electrode described above with reference to FIG. 3.

In an embodiment, the first gate electrode GE1 and the second gate electrode GE2 may respectively overlap the first semiconductor layer Act1 and the second semiconductor layer Act2 with a first insulating layer 111 therebetween. The first insulating layer 111 may be disposed under the first gate electrode GE1 and the second gate electrode GE2. The first insulating layer 111 may include an inorganic insulating material such as silicon oxide, silicon nitride, silicon oxynitride, aluminum oxide, titanium oxide, tantalum oxide, hafnium oxide, and/or zinc oxide.

In an embodiment, the first gate electrode GE1 and the second gate electrode GE2 may each include a conductive material including molybdenum (Mo), aluminum (Al), copper (Cu), titanium (Ti), and/or the like. The first gate electrode GE1 and the second gate electrode GE2 may each include multiple layers or a single layer including the aforementioned materials. For example, the first gate electrode GE1 and the second gate electrode GE2 may each have a single-layer structure including Mo.

In an embodiment, the first gate electrode GE1 may be arranged on a same layer as the first lower electrode CE1 of the first capacitor Cst. In an embodiment, a layer may have functions of both of the first gate electrode GE1 and the first lower electrode CE1 of the first capacitor Cst. For example, a portion of the first gate electrode GE1 may include the first lower electrode CE1 of the first capacitor Cst. In other words, a portion of the first lower electrode CE1 of the first capacitor Cst may include the first gate electrode GE1.

In an embodiment, a second insulating layer 113 may be disposed on the first gate electrode GE1 and the second gate electrode GE2. The second insulating layer 113 may include an inorganic insulating material such as silicon oxide, silicon nitride, silicon oxynitride, aluminum oxide, titanium oxide, tantalum oxide, hafnium oxide, zinc oxide, and/or the like.

In an embodiment, the first upper electrode CE2 of the first capacitor Cst may include a conductive material including Mo, Al, Cu, Ti, and/or the like and may include multiple layers or a single layer including the aforementioned materials. In some embodiments, the first upper electrode CE2 of the first capacitor Cst may include a material that is relatively low-resistant. For example, the first lower electrode CE1 of the first capacitor Cst may include a single layer including Mo, and the first upper electrode CE2 of the first capacitor Cst may include a multi-layer structure including an Al layer and a Ti layer.

In an embodiment, a third insulating layer 115 may be disposed on the first upper electrode CE2 of the first capacitor Cst. The third insulating layer 115 may include an inorganic insulating material such as silicon oxide, silicon nitride, silicon oxynitride, aluminum oxide, titanium oxide, tantalum oxide, hafnium oxide, zinc oxide, and/or the like.

In an embodiment, the second capacitor Chold may include the second lower electrode CE3 and the second upper electrode CE4 overlapping each other.

In an embodiment, the second lower electrode CE3 of the second capacitor Chold and the first upper electrode CE2 of the first capacitor Cst may be arranged on a same layer. In an embodiment, a layer may have functions of both of the second lower electrode CE3 of the second capacitor Chold and the first upper electrode CE2 of the first capacitor Cst. For example, the second lower electrode CE3 of the second capacitor Chold may include the first upper electrode CE2 of the first capacitor Cst. In other words, a conductive layer disposed on the first lower electrode CE1 and overlapping the first lower electrode CE1 may have functions both of the first upper electrode CE2 of the first capacitor Cst and the second lower electrode CE3 of the second capacitor Chold.

In an embodiment, the second upper electrode CE4 may include a conductive material including Mo, Al, Cu, Ti, and/or the like, and may include multiple layers or a single layer including the aforementioned materials. For example, the second upper electrode CE4 may include a double-layered structure including an Al layer and a Ti layer.

In an embodiment, a fourth insulating layer 117 may be disposed on the second capacitor Chold. The fourth insulating layer 117 may include an inorganic insulating material such as silicon oxide, silicon nitride, silicon oxynitride, aluminum oxide, titanium oxide, tantalum oxide, hafnium oxide, zinc oxide, and/or the like.

In an embodiment, a first connection metal CM1, a second connection metal CM2, a third connection metal CM3, and the first scan line GWL may each be disposed on the fourth insulating layer 117. A portion of the first connection metal CM1 may contact the second semiconductor layer Act2 through a contact hole penetrating insulating layers disposed between the second semiconductor layer Act2 and the first connection metal CM1, and another portion of the first connection metal CM1 may contact the first upper electrode CE2 of the first capacitor Cst through a contact hole penetrating insulating layers disposed between the first upper electrode CE2 of the first capacitor Cst and the first connection metal CM1. A second connection metal CM2 may contact the second semiconductor layer Act2 through a contact hole penetrating insulating layers disposed between the second semiconductor layer Act2 and the second connection metal CM2. A third connection metal CM3 may contact the second upper electrode CE4 of the second capacitor Chold through a contact hole penetrating an insulating layer disposed between the second upper electrode CE4 of the second capacitor Chold and the third connection metal CM3. The first scan line GWL may contact the second gate electrode GE2 through a contact hole penetrating insulating layers disposed between the second gate electrode GE2 and the first scan line GWL.

In an embodiment, the first connection metal CM1, the second connection metal CM2, the third connection metal CM3, and the first scan line GWL may each include a conductive material including Al, Cu, Ti, and/or the like, and may include multiple layers or a single layer including the aforementioned materials. For example, the first connection metal CM1, the second connection metal CM2, the third connection metal CM3, and the first scan line GWL may each include a triple-layered structure including a Ti layer, an Al layer, and a Ti layer.

In an embodiment, a fifth insulating layer 119 may be disposed on the first connection metal CM1, the second connection metal CM2, the third connection metal CM3, and the first scan line GWL. The fifth insulating layer 119 may include benzocyclobutene (BCB), hexamethyldisiloxane (HMDSO), polymethylmethacrylate (PMMA), a general-purpose polymer such as polystyrene (PS), a polymer-derivative including a phenol-based group, an acrylic-based polymer, an imide-based polymer (such as polyimide), an arylether-based polymer, an amide-based polymer, a fluoride-based polymer, a p-xylene-based polymer, a vinylalcohol-based polymer, blends thereof, and/or the like.

In an embodiment, the driving voltage line PL and the data line DL may each be arranged on the fifth insulating layer 119. The driving voltage line PL and the data line DL may each include a conductive material including Al, Cu, Ti, and/or the like, and may include multiple layers and a single layer including the aforementioned material. For example, the driving voltage line PL and the data line DL may each include a triple-layered structure including a Ti layer, an Al layer, and a Ti layer.

In an embodiment, a sixth insulating layer 121 may be disposed on the driving voltage line PL and the data line DL. The sixth insulating layer 121 may include BCB, HMDSO, PMMS, a general-purpose polymer such as PS, a polymer derivative having a phenol-based group, an acrylic-based polymer, an imide-based polymer (such as polyimide), an arylether-based polymer, an amide-based polymer, a fluoride-based polymer, a p-xylene-based polymer, a vinylalcohol-based polymer, and/or blends thereof.

In an embodiment, the light-emitting diode LED may include a subpixel electrode 210 disposed on the sixth insulating layer 121, an intermediate layer 220 including an organic emission layer, and a counter electrode 230.

In an embodiment, the subpixel circuit PC may be disposed on the sixth insulating layer 121 and electrically connected to the subpixel circuit PC at a position that is not shown in FIG. 4. In some embodiments, the subpixel electrode 210 may include a reflective layer, which includes Ag, Mg, Al, Pt, Pd, Au, Ni, Nd, Ir, Cr, and/or compounds thereof, and/or a transparent or semi-transparent electrode layer formed on the reflective layer. The transparent or semi-transparent electrode layer may include at least one selected from a group including indium tin oxide (ITO), indium zinc oxide (IZO), zinc oxide (ZnO), indium oxide (In₂O₃), indium gallium oxide (IGO), and aluminum zinc oxide (AZO). In some embodiments, the subpixel electrode 210 may be provided in the form of ITO/Ag/ITO.

In an embodiment, a bank layer 123 may include one or more organic insulating materials selected from a group including polyimide, polyamide, an acrylic resin, BCB, and/or a phenol resin. Alternatively, the bank layer 123 may include an inorganic insulating material such as silicon nitride, silicon oxide, and/or silicon oxynitride.

In an embodiment, at least a portion of the intermediate layer 220 may be arranged in an opening of the bank layer 123. The intermediate layer 220 may include an emission layer, e.g., an organic emission layer. The organic emission layer may include an organic material including a fluorescent or phosphorescent material, the organic material emitting red, green, blue or white light. The organic emission layer may include a low-molecular weight organic material or a high-molecular organic material.

In an embodiment, the intermediate layer 220 may include a common layer disposed under and/or on the organic emission layer. The common layer may include a hole transport layer (HTL), a hole injection layer (HIL), an electron transport layer (ETL), and/or an electron injection layer (EIL), and may cover a plurality of subpixel electrodes, like the counter electrode 230. In other words, the counter electrode 230 and the common layer may be shared by a plurality of light-emitting diodes LED.

In an embodiment, the counter electrode 230 may include a light-transmitting electrode or a reflective electrode. In some embodiments, the counter electrode 230 may include a transparent or semi-transparent electrode, and may include a metal thin-film having a small work function and including Li, Ca, Al, Ag, Mg, and/or compounds thereof, or materials having a multi-layers structures such as LiF/Ca, LiF/Al. In addition, a transparent conductive oxide (TCO) film including ITO, IZO, ZnO, In₂O₃, and/or the like may be further disposed on the metal thin-film.

In an embodiment, the light-emitting diode LED may be covered by an encapsulation layer including at least one organic encapsulation layer and at least one inorganic encapsulation layer.

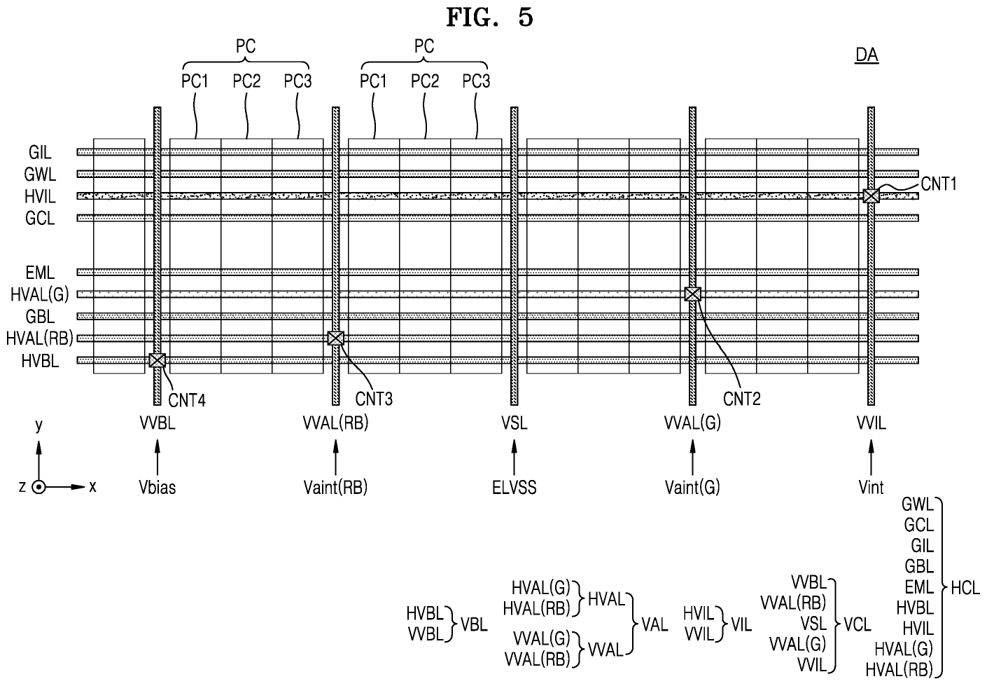

FIG. 5 is a top-plan view schematically illustrating wirings as arranged in the display area DA of the display device 1 (see FIG. 2), according to an embodiment. The subpixel circuits PC may be arranged in the first direction (e.g., the ±x direction) and the second direction (e.g., the ±y direction), and FIG. 5 illustrates the subpixel circuits PC arranged in a same row.

In an embodiment, the subpixel circuits PC may be connected to the light-emitting diodes LED (see FIG. 3), respectively. Hereinafter, for convenience explanation, the subpixel circuits in electrical connection with the first light-emitting diode, the second light-emitting diode, and the third light-emitting diode will be described as a first subpixel circuit PC1, a second subpixel circuit PC2, and a third subpixel circuit PC3 in FIG. 5, respectively, and the first, second, and third light-emitting diode are omitted in FIG. 5. In an embodiment, the first subpixel circuit PC1, the second subpixel circuit PC2, and the third subpixel circuit PC3 may be repeatedly arranged in the first direction (e.g., the ±x direction). The first subpixel circuit PC1 may be electrically connected to the first light-emitting diode configured to emit light having a first color, the second subpixel circuit PC2 may be electrically connected to the second light-emitting diode configured to emit light having a second color, and the third subpixel circuit PC3 may be electrically connected to the third light-emitting diode configured to emit light having a third color. In some embodiments, the first color, the second color, and the third color, which are colors of different lights, may be selected from among red, green, and blue. Hereinafter, for convenience of explanation, an embodiment in which the third subpixel circuit PC3 is electrically connected to the third light-emitting diode configured to emit green light, and the first subpixel circuit PC1 and the second subpixel circuit PC2 are respectively in electrical connection with the first light-emitting diode configured to emit blue light and the second light-emitting diode configured to emit red light is provided.

In an embodiment, lines electrically connected to the subpixel circuits PC, e.g., first conductive lines (hereinafter, referred to horizontal conductive lines HCL) extending in the first direction (e.g., the ±x direction) and second conductive lines (hereinafter, referred to as vertical conductive lines VCL) extending in the second direction (e.g., the ±y direction), may be arranged in the display area DA.

In an embodiment, the horizontal conductive lines HCL extending in the first direction (e. g., the ±x direction) may include the first scan line GWL, the second scan line GCL, the third scan line GIL, the fourth scan line GBL, the emission control line EML, a first horizontal voltage line HVIL, a second horizontal voltage line HVAL, and a third horizontal voltage line HVBL. The second horizontal voltage line HVAL may include a 2-1 horizontal voltage line HVAL(G) and a 2-2 horizontal voltage line HVAL(RB).

In an embodiment, the first scan line GWL, the second scan line GCL, the third scan line GIL, the emission control line EML, the 2-2 horizontal voltage line HVAL(RB) and the third horizontal voltage line HVBL may be arranged on a same layer and may include a same material. For example, the first scan line GWL, the second scan line GCL, the third scan line GIL, the emission control line EML, the 2-2 horizontal voltage line HVAL(RB), and the third horizontal voltage line HVBL may each be disposed on the fourth insulating layer 117 described above with reference to FIG. 4.

In an embodiment, the 2-1 horizontal voltage line HVAL(G) may be arranged on a same layer (e.g., the third insulating layer 115) as the second upper electrode CE4 described above with FIG. 4 and may include a same material as the second upper electrode CE4.

In an embodiment, the first horizontal voltage line HVIL may be disposed on a same layer (e.g., the second insulating layer 113) as the first upper electrode CE2 described above with reference to FIG. 4 and may include a same material as the first upper electrode CE2.

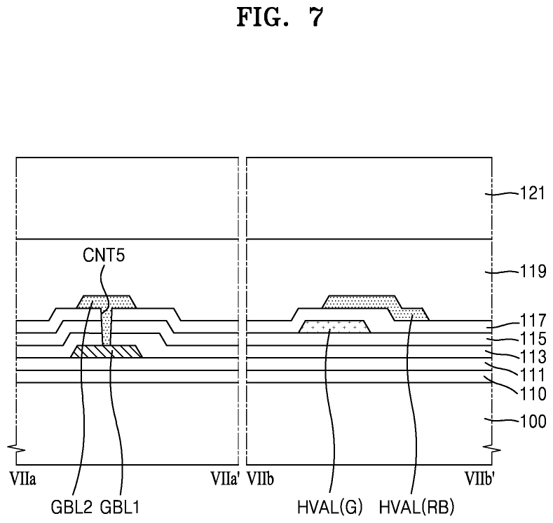

In an embodiment, the fourth scan line GBL may include a line arranged on a same layer (e.g., the first insulating layer 111) as the first gate electrode GE1 and/or the first lower electrode CE1 described above with reference to FIG. 4 and a line arranged on a same layer (e.g., the fourth insulating layer 117) as the first scan line GWL. Details thereof will be described below with reference to FIG. 7.

In an embodiment, vertical conductive lines VCL extending in the second direction (e.g., ±y direction) may include a first vertical voltage line VVIL configured to provide a first initialization voltage Vint, a second vertical voltage line VVAL configured to provide a second initialization voltage Vaint (see FIG. 3), a third vertical voltage line VVBL configured to provide the bias voltage Vbias, and a common voltage line VSL configured to provide the common voltage ELVSS. The second vertical voltage line VVAL may include a 2-1 vertical voltage line VVAL(G) configured to provide a 2-1 initialization voltage Vaint(G) and a 2-2 vertical voltage line VVAL(RB) configured to provide a 2-2 initialization voltage Vaint(RB).

In an embodiment, the first vertical voltage line VVIL, the second vertical voltage line VVAL (e.g., the 2-1 vertical voltage line VVAL(G) and the 2-2 vertical voltage line VVAL(RB)), the third vertical voltage line VVBL, and the common voltage line VSL may be arranged on a same layer and may include a same material. For example, the first vertical voltage line VVIL, the second vertical voltage line VVAL (e.g., the 2-1 vertical voltage line VVAL(G) and the 2-2 vertical voltage line VVAL(RB)), the third vertical voltage line VVBL, and the common voltage line VSL may each be arranged on the fifth insulating layer 119 described above with reference to FIG. 4.

In an embodiment, the first vertical voltage line VVIL, the second vertical voltage line VVAL (e.g., the 2-1 vertical voltage line VVAL(G) and the 2-2 vertical voltage line VVAL(RB)), the third vertical voltage line VVBL, and the common voltage line VSL may be arranged apart from one another. A plurality of subpixel circuit PC may be arranged between the vertical conductive lines VCL that are adjacent to each other. For example, three subpixel circuits PC, e.g., the first subpixel circuit PC1, the second subpixel circuit PC2, and the third subpixel circuit PC3 may be arranged between two lines neighboring each other from among the first vertical voltage line VVIL, the second vertical voltage line VVAL (e.g., the 2-1 vertical voltage line VVAL(G) and the 2-2 vertical voltage line VVAL(RB)), the third vertical voltage line VVBL, and the common voltage line VSL.

In an embodiment, the first vertical voltage line VVIL may be electrically connected to the first horizontal voltage line HVIL through a first contact hole CNT1. The first vertical voltage line VVIL and the first horizontal voltage line HVIL electrically connected to each other may correspond to the first voltage line VIL described above with reference to FIG. 3. In other words, the first voltage line VIL described with reference to FIG. 3 may include two sub-voltage lines electrically connected to each other, one of which may include the first vertical voltage line VVIL and another of which may include the first horizontal voltage line HVIL.

In an embodiment, the first vertical voltage line VVIL may be electrically connected to the first horizontal voltage line HVIL through the first contact hole CNT1, and the fourth transistor provided in each of the first subpixel circuit PC1, the second subpixel circuit PC2, and the third subpixel circuit PC3 may be electrically connected to the first horizontal voltage line HVIL, and therefore, the first initialization voltage Vint may be provided to the fourth transistor provided in each of the first subpixel circuit PC1, the second subpixel circuit PC2, and the third subpixel circuit PC3.

In an embodiment, the second vertical voltage line VVAL may be electrically connected to the second horizontal voltage line HVAL through a contact hole.

For example, in an embodiment, the 2-1 vertical voltage line VVAL(G) configured to apply the 2-1 initialization voltage Vaint(G) may be electrically connected to the 2-1 horizontal voltage line HVAL(G) through a second contact hole CNT2. The 2-1 vertical voltage line VVAL(G) and the 2-1 horizontal voltage line HVAL(G) electrically connected to each other may correspond to the second voltage line VAL electrically connected to the seventh transistor of any one subpixel circuit selected from among the first subpixel circuit PC1, the second subpixel circuit PC2, and the third subpixel circuit PC3, e.g., the seventh transistor T7 of the third subpixel circuit PC3. The third subpixel circuit PC3, to which the 2-1 initialization voltage Vaint(G) described above is applied, may be electrically connected to the third light-emitting diode configured to emit green light.

In an embodiment, a same initialization voltage, e.g., the 2-2 initialization voltage Vaint(RB), may be provided to the seventh transistor of each of the first subpixel circuit PC1 and the second subpixel circuit PC2 respectively connected to the first light-emitting diode configured to emit red light and the second light-emitting diode configured to emit blue light. For example, in an embodiment, the 2-2 vertical voltage line VVAL(RB) configured to apply the 2-2 initialization voltage Vaint(RB) may be electrically connected to the 2-2 horizontal voltage line HVAL(RB) through a third contact hole CNT3. The 2-2 vertical voltage line VVAL(RB) and the 2-2 horizontal voltage line HVAL(RB) electrically connected to each other may correspond to the second voltage line VAL electrically connected to the seventh transistor of each of the first subpixel circuit PC1 and the second subpixel circuit PC2.

In an embodiment, the third vertical voltage line VVBL may be electrically connected to the third horizontal voltage line HVBL through a fourth contact hole CNT4. The third vertical voltage line VVBL and the third horizontal voltage line HVBL electrically connected to each other may correspond to the third voltage line VBL described above with reference to FIG. 3.

In an embodiment, the third vertical voltage line VVBL may be electrically connected to the third horizontal voltage line HVBL through the fourth contact hole CNT4, and the ninth transistor provided in each of the first subpixel circuit PC1, the second subpixel circuit PC2, and the third subpixel circuit PC3 may be electrically connected to the third horizontal voltage line HVBL, and accordingly, the bias voltage Vbias may be provided to the ninth transistor provided in each of the first subpixel circuit PC1, the second subpixel circuit PC2, and the third subpixel circuit PC3.

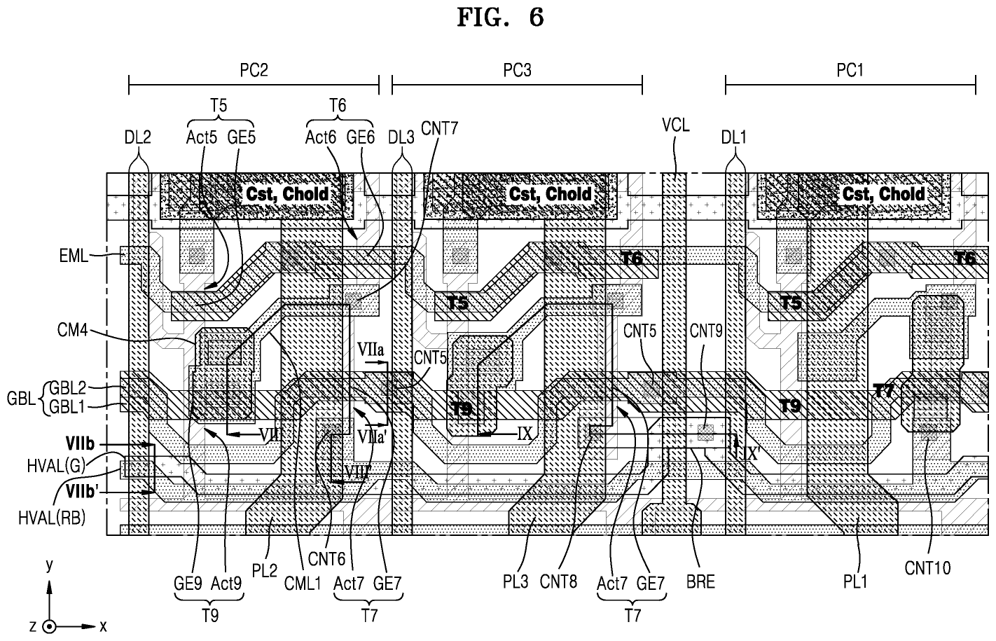

FIG. 6 is a top-plan view schematically illustrating some of the transistors arranged in the display area DA (see FIG. 5) of the display device 1 (see FIG. 2), according to an embodiment, and the conductive lines electrically connected to the transistors. FIG. 6, which illustrates an extracted image of a portion of the display area DA shown in FIG. 5, illustrates the second subpixel circuit PC2 and the third subpixel circuit PC3 arranged at one side of the vertical conductive line VCL and the first subpixel circuit PC1 arranged at another side of the vertical conductive line. For example, in an embodiment, the vertical conductive line VCL shown in FIG. 6 may include any one selected from among the first vertical voltage line VVIL, the 2-1 vertical voltage line VVAL(G), the 2-2 vertical voltage line VVAL(RB), the third vertical voltage line VVBL, and the common voltage line VSL described above with reference to FIG. 5.

For convenience of explanation, in an embodiment, FIG. 6 illustrates a portion of each of the first subpixel circuit PC1, the second subpixel circuit PC2, and the third subpixel circuit PC3. The first subpixel circuit PC1, the second subpixel circuit PC2, and the third subpixel circuit PC3 may be electrically connected to the data line DL1, DL2, DL3, and the driving voltage lines PL1, PL2, and PL3, respectively. On a plane, each of the first subpixel circuit PC1, the second subpixel circuit PC2, and the third subpixel circuit PC3 may include the fifth transistor T5, the sixth transistor T6, the seventh transistor T7, and the ninth transistor T9 disposed under the first capacitor Cst and the second capacitor Chold. The first capacitor Cst and the second capacitor Chold may overlap each other, as described above with reference to FIG. 4.

In an embodiment, the emission control line EML may extend in the first direction (e.g., the ±x direction) and overlap a portion of each of a semiconductor layer Act5 of the fifth transistor T5 and a semiconductor layer Act6 of the sixth transistor T6. In the emission control line EML, a portion overlapping the semiconductor layer Act5 of the fifth transistor T5 may include a gate electrode GE5 of the fifth transistor T5, and a portion overlapping the semiconductor layer Act6 of the sixth transistor T6 may include a gate electrode GE6 of the sixth transistor T6.

In an embodiment, the seventh transistor T7 may include a semiconductor layer Act7 integrally connected to the semiconductor layer Act6 of the sixth transistor T6, and the ninth transistor T9 may include a semiconductor layer Act9 integrally connected to the semiconductor layer Act5 of the fifth transistor T5.

In an embodiment, the fourth scan line GBL may extend in the first direction (e.g., the ±x direction) and overlap a portion of each of the semiconductor layer Act7 of the seventh transistor T7 and the semiconductor layer Act9 of the ninth transistor T9. The fourth scan line GBL may include two sub-scan lines respectively disposed on different layers with an insulating layer therebetween and electrically connected to each other. For example, the fourth scan line GBL may include a 4-1 scan line GBL1 and a 4-2 scan line GBL2. The 4-1 scan line GBL1 and the 4-2 scan line GBL2 may each extend in the first direction (e.g., the ±x direction), and may be electrically connected to each other through a fifth contact hole CNT5 penetrating an insulating layer between the 4-1 scan line GBL1 and the 4-2 scan line GBL2. A resistance of the fourth scan line GBL may be reduced through the 4-1 scan line GBL1 and the 4-2 scan line GBL2 electrically connected to each other, and therefore, a display device that may be driven at a high rate without decrease in the resolution may be provided.

In an embodiment, a portion of the fourth scan line GBL, e.g., a portion of the 4-1 scan line GBL1 overlapping the semiconductor layer Act7 of the seventh transistor T7, may include a gate electrode GE7 of the seventh transistor T7. A portion of the fourth scan line GBL, e.g., a portion of the 4-1 scan line GBL1 overlapping the semiconductor layer Act9 of the ninth transistor T9 may include a ninth gate electrode GE9 of the ninth transistor T9.

In an embodiment, the 2-2 horizontal voltage line HVAL(RB) may extend in the first direction (e.g., the ±x direction). The 2-2 horizontal voltage line HVAL(RB) may be electrically connected to the semiconductor layer Act7 of the seventh transistor T7 of each of the second subpixel circuit PC2 and the first subpixel circuit PC1. For example, in an embodiment, a portion of the 2-2 horizontal voltage line HVAL(RB) may overlap the semiconductor layer Act7 of seventh transistor T7 of the second subpixel circuit PC2 and may be connected thereto through a sixth contact hole CNT6 between the portion of the 2-2 horizontal voltage line HVAL(RB) and the semiconductor layer Act7 of the seventh transistor T7 of the second subpixel circuit PC2. Another portion of the 2-2 horizontal voltage line HVAL(RB) may overlap the semiconductor layer Act7 of the seventh transistor T7 of the first subpixel circuit PC1 and may be electrically connected thereto through a tenth contact hole CNT10 arranged between the 2-2 horizontal voltage line HVAL(RB) and the semiconductor layer Act7 of the seventh transistor T7 of the first subpixel circuit PC1. One of the second subpixel circuit PC2 and the first subpixel circuit PC1 may be electrically connected to a light-emitting diode configured to emit red light, and another one may be electrically connected to a light-emitting diode configured to emit blue light.

In an embodiment, the 2-1 horizontal voltage line HVAL(G) may extend in the first direction (e.g., the ±x direction). The 2-1 horizontal voltage line HVAL(G) may be electrically connected to the semiconductor layer Act7 of the seventh transistor T7 of the third subpixel circuit PC3. For example, as shown in FIG. 6, the 2-1 horizontal voltage line HVAL(G) may be electrically connected to the semiconductor layer Act7 of the seventh transistor T7 of the third subpixel circuit PC3 through a bridge electrode BRE.

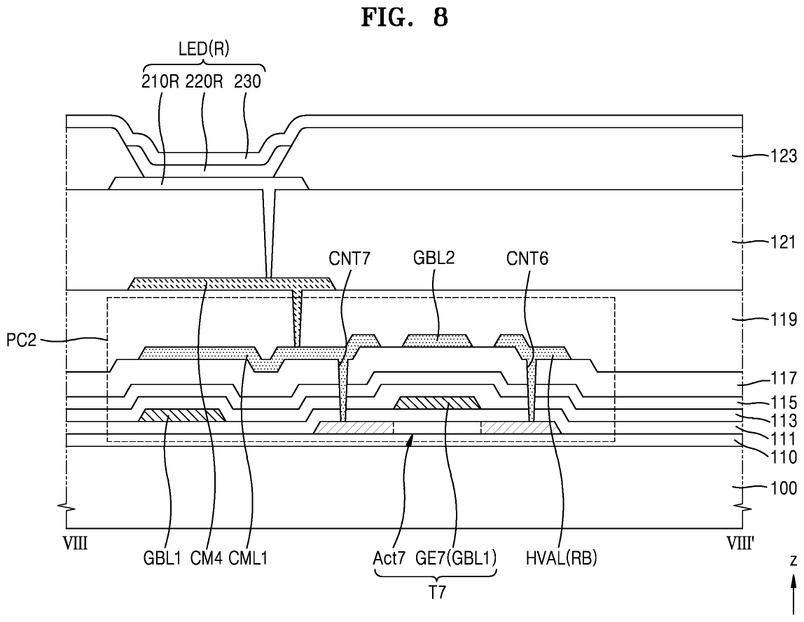

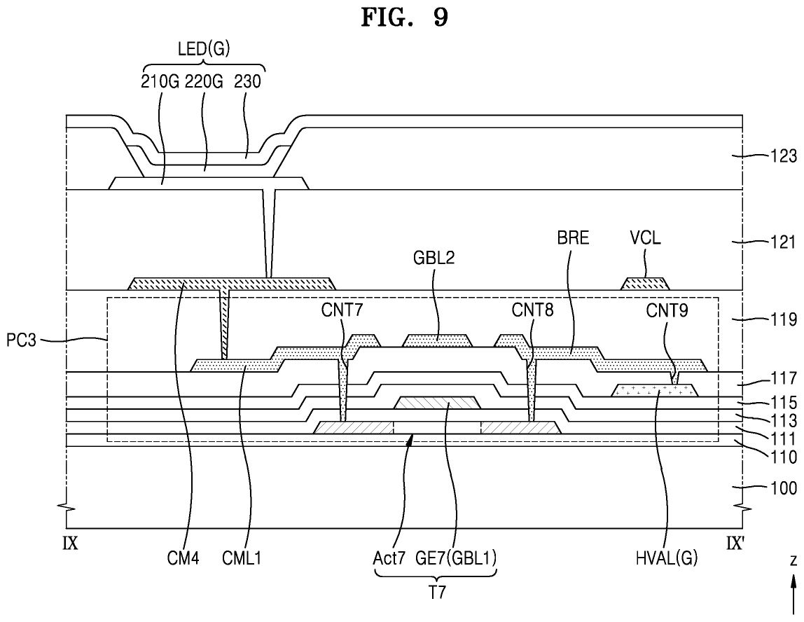

In an embodiment, the bridge electrode BRE may have an isolated shape. A portion of the bridge electrode BRE may overlap a portion of the semiconductor layer Act7 of the seventh transistor T7 of the third subpixel circuit PC3, and another portion may overlap a portion of the 2-1 horizontal voltage line HVAL(G). The bridge electrode BRE may be electrically connected to the semiconductor layer Act7 of the seventh transistor T7 of the third subpixel circuit PC3 through an eighth contact hole CNT8, and may be electrically connected to a portion of the 2-1 horizontal voltage line HVAL(G) through the ninth contact hole CNT9. The bridge electrode BRE may be disposed on the semiconductor layer Act7 of the seventh transistor T7 of the third subpixel circuit PC3 and the 2-1 horizontal voltage line HVAL(G). The bridge electrode BRE may be arranged to be disposed on a same layer (e.g., the fourth insulating layer 117) as the 2-2 horizontal voltage line HVAL(RB) (see FIG. 8 and FIG. 9).

According to one or more embodiments, the seventh transistor T7 of the third subpixel circuit PC3 may be electrically connected to the 2-1 horizontal voltage line HVAL(G), and the seventh transistors T7 of the first subpixel circuit PC1 and the second subpixel circuit PC2 may be electrically connected to the 2-2 horizontal voltage line HVAL(RB). Accordingly, different voltages may be respectively arranged according to requirements and/or a voltage may be applied at different timings, and high-rate driving may be facilitated without the decrease in resolution. In addition, as the 2-1 horizontal voltage line HVAL(G) and the 2-2 horizontal voltage line HVAL(RB) are respectively arranged on different layers, the display device 1 may be manufactured while adjusting positions of the transistors of the first subpixel circuit PC1, the second subpixel circuit PC2, and the third subpixel circuit PC3 identical to one another. A portion of the 2-2 horizontal voltage lines HVAL(RB) arranged adjacent to each other may overlap a portion of the 2-1 horizontal voltage line HVAL(G).

FIG. 7 is a cross-sectional view of the display device 1 (see FIG. 2), according to an embodiment, which illustrates a cross-section taken along a line VIIa-VIIa′ shown in FIG. 6 and a cross-section taken along a line VIIb-VIIb′ shown in FIG. 6.

In an embodiment and referring to the cross-section taken along the line VIIa-VIIa′ shown in FIG. 7, the 4-1 scan line GBL1 may be disposed on the first insulating layer 111, and may include a same material as the first gate electrode GE1 and/or the first lower electrode CE1 of the first capacitor Cst described above with reference to FIG. 4. The 4-2 scan line GBL2 may be disposed on the fourth insulating layer 117, and may include a same material as the first scan line GWL described above with reference to FIG. 4. The 4-2 scan line GBL2 may be electrically connected to the 4-1 scan line GBL1 through the fifth contact hole CNT5 penetrating an insulating layer, e.g., the second insulating layer 113, the third insulating layer 115, and the fourth insulating layer 117, arranged between the 4-1 scan line GBL1 and the 4-2 scan line GBL2.

In an embodiment and referring to the cross-section taken along the line VIIb-VIIb′ shown in FIG. 7, the 2-1 horizontal voltage line HVAL(G) and the 2-2 horizontal voltage line HVAL(RB) may be respectively arranged on different layers. For example, the 2-1 horizontal voltage line HVAL(G) may be arranged on a same layer (e.g., the third insulating layer 115) as the second upper electrode CE4 of the second capacitor Chold. The 2-1 horizontal voltage line HVAL(G) may include a same material as a material of the second upper electrode CE4 of the second capacitor Chold described above with reference to FIG. 4. The 2-2 horizontal voltage line HVAL(RB) may be disposed on the fourth insulating layer 117 and may include a same material as the first scan line GWL described above with reference to FIG. 4 and the 4-2 scan line GBL2 shown in FIG. 7. The 2-1 horizontal voltage line HVAL(G) disposed under the fourth insulating layer 117 and the 2-2 horizontal voltage line HVAL(RB) disposed on the fourth insulating layer 117 may be electrically insulated from each other.

FIG. 8 is a cross-sectional view of a display device, according to an embodiment, which illustrates a cross-section taken along a line VIII-VIII′ shown in FIG. 6.

In an embodiment and referring to FIG. 8, the seventh transistor T7 of the second subpixel circuit PC2 may include the semiconductor layer Act7 disposed on the buffer layer 110 and the gate electrode GE7 overlapping the semiconductor layer Act7 with the first insulating layer 111 therebetween. As described with reference to FIG. 6, the gate electrode GE7 of the seventh transistor T7 may include a portion of the 4-1 scan line GBL1.

In an embodiment, the seventh transistor T7 of the second subpixel circuit PC2 may be electrically connected to a subpixel electrode 210R of a second light-emitting diode LED(R) through a first connection line CML1 and a fourth connection metal CM4. The seventh transistor T7 of the second subpixel circuit PC2 may electrically connect the 2-2 horizontal voltage line HVAL(RB) to the subpixel electrode 210R of the second light-emitting diode LED(R), in response to a signal from the fourth scan line GBL (see FIG. 6). The second light-emitting diode LED(R) may include an intermediate layer 220R disposed between the subpixel electrode 210R and the counter electrode 230. The intermediate layer 220R may include, for example, an emission layer configured to emit red light. For convenience of explanation, a light-emitting diode configured to emit red light is described with reference to FIG. 8, according to an embodiment. However, in other embodiments, the light-emitting diode may include a light-emitting diode configured to emit blue light.

As shown in FIG. 8, in an embodiment, the first connection line CML1 may be electrically connected to the semiconductor layer Act7 of the seventh transistor T7 through a seventh contact hole CNT7. As shown in FIG. 6, the semiconductor layer Act7 of the seventh transistor T7 and the semiconductor layer Act6 of the sixth transistor T6 are connected to each other, and therefore, the first connection line CML1 may be referred to as being electrically connected to the semiconductor layer Act6 (see FIG. 6) of the sixth transistor T6 (see FIG. 6) through the seventh contact hole CNT7.

In an embodiment, the semiconductor layer Act7 of the seventh transistor T7 may include a channel area overlapping the gate electrode GE7, a first impurity doping area arranged at a side of the channel area, and a second impurity doping area arranged at another side of the channel area. The first connection line CML1 may be electrically connected, through the seventh contact hole CNT7, to the first impurity doping area of the semiconductor layer Act7 of the seventh transistor T7 (or the first impurity doping area of the semiconductor layer Act6 of the sixth transistor T6).

As shown in FIG. 8, in an embodiment, the second impurity doping area may be electrically connected to the 2-2 horizontal voltage line HVAL(RB) through the sixth contact hole CNT6. The 2-2 horizontal voltage line HVAL(RB) may be disposed on the fourth insulating layer 117. The sixth contact hole CNT6 and the seventh contact hole CNT7 may each penetrate the first insulating layer 111, the second insulating layer 113, the third insulating layer 115, and the fourth insulating layer 117.

In an embodiment, the first connection line CML1 may be arranged on a same layer (e.g., the fourth insulating layer 117) as the 4-2 scan line GBL2 and the 2-2 horizontal voltage line HVAL(RB). The first connection line CML1 may include a same material as a material of the 4-2 scan line GBL2 and the 2-2 horizontal voltage line HVAL(RB).

In an embodiment, the fourth connection metal CM4 may be disposed on a fifth insulating layer 119. The fourth connection metal CM4 may include a same material as a material of the data line DL and the driving voltage line PL described above with reference to FIG. 4.

FIG. 9 is a cross-sectional view of the display device, according to an embodiment, which illustrates a cross-section taken along a line IX-IX′ shown in FIG. 6.

In an embodiment, FIG. 9 illustrates that the seventh transistor T7 included in the third subpixel circuit PC3 and a third light-emitting diode LED(G) are electrically connected to each other through the first connection line CML1 and the fourth connection metal CM4. The seventh transistor T7 of the third subpixel circuit PC3 may electrically connect the 2-1 horizontal voltage line HVAL(G) to a subpixel electrode 210G of the third light-emitting diode LED(G), in response to a signal from the fourth scan line GBL (see FIG. 6).

In an embodiment, as a structure of electrical connection between the seventh transistor T7 included in the third subpixel circuit PC3 and the third light-emitting diode LED(G), which is shown in FIG. 9, is substantially identical to a structure of the electrical connection between the seventh transistor T7 included in the second subpixel circuit PC2 and the second light-emitting diode LED(R), which is described with reference to FIG. 8, descriptions of the structure of electrical connection shown in FIG. 9 will be replaced with the descriptions with reference to FIG. 8.

In an embodiment, the semiconductor layer Act7 of the seventh transistor T7 included in the third subpixel circuit PC3 may include the channel area overlapping the gate electrode GE7, the first impurity doping area arranged at a side of the channel area, and the second impurity doping area arranged at another side of the channel area.

As shown in FIG. 9, in an embodiment, the first impurity doping area may be electrically connected to the first connection line CML1 through the seventh contact hole CNT7. As shown in FIG. 9, the second impurity doping area may be connected to the 2-1 horizontal voltage line HVAL(G) through the bridge electrode BRE.

In an embodiment, the bridge electrode BRE may be arranged on a same layer as the 2-2 horizontal voltage line HVAL(RB) described above with reference to FIGS. 6 and 7. For example, the bridge electrode BRE may be disposed on the fourth insulating layer 117. A portion of the bridge electrode BRE may be electrically connected to the second impurity doping area of the semiconductor layer Act7 of the seventh transistor T7 through the eighth contact hole CNT8. The eighth contact hole CNT8 may penetrate the first insulating layer 111, the second insulating layer 113, the third insulating layer 115, and the fourth insulating layer 117.

In an embodiment, another portion of the bridge electrode BRE may be electrically connected to the 2-1 horizontal voltage line HVAL(G) through the ninth contact hole CNT9. The 2-1 horizontal voltage line HVAL(G) may be disposed on the third insulating layer 115, and the ninth contact hole CNT9 may penetrate the fourth insulating layer 117.

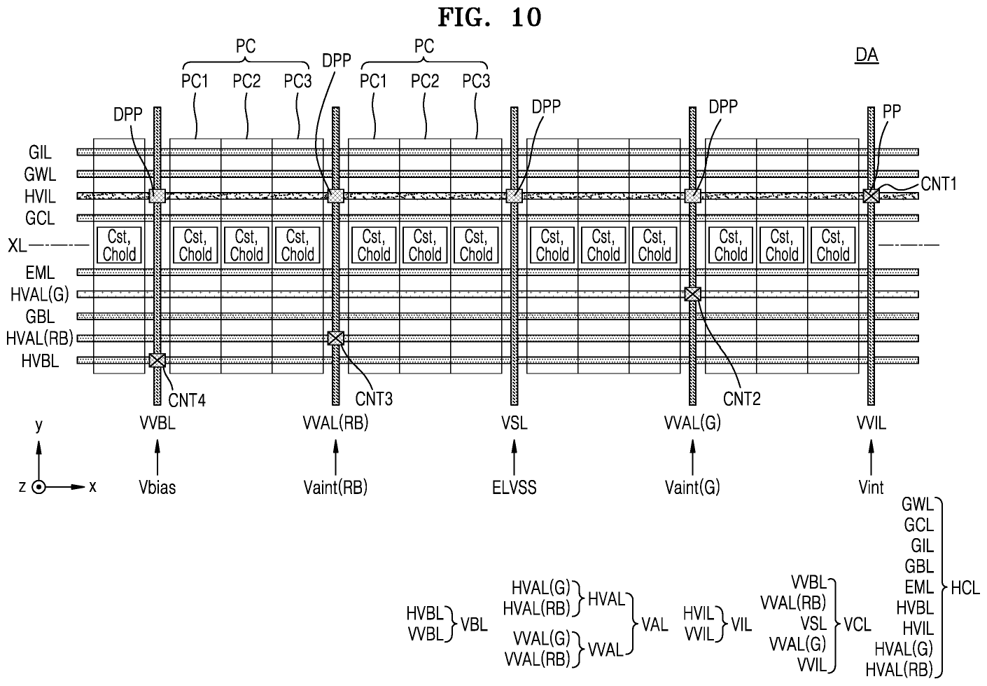

FIG. 10 is a top-plan view schematically illustrating the wirings as arranged in the display area DA of the display device 1 (see FIG. 2), according to an embodiment. As the structure shown in FIG. 10 includes the structure described above with reference to FIG. 5, descriptions of the same configurations will be substituted with the descriptions of FIG. 5, and hereinafter, differences will be mainly described.

In an embodiment and referring to FIG. 10, at least any one selected from among the vertical conductive lines VCL extending in the second direction, e.g., the first vertical voltage line VVIL, the 2-1 vertical voltage line VVAL(G), the 2-2 vertical voltage line VVAL(RB), the third vertical voltage line VVBL, and the common voltage line VSL may include a pattern portion.

In an embodiment, referring to FIG. 10, the first vertical voltage line VVIL may include a first pattern portion PP for electrical contact with the first horizontal voltage line HVIL, and the first vertical voltage line VVIL may be electrically connected to the first horizontal voltage line HVIL through the first contact hole CNT1 provided right under the first pattern portion PP. A width (e.g., a width in the first direction) of the first pattern portion PP may be greater than a width (e.g., the width in the first direction) of another portion of the first vertical voltage line VVIL. The first contact hole CNT1 may penetrate an insulating layer between the first horizontal voltage line HVIL and the first vertical voltage line VVIL.

In an embodiment, other vertical conductive lines VCL, e.g., the 2-1 vertical voltage line VVAL(G), the 2-2 vertical voltage line VVAL(RB), the third vertical voltage line VVBL, and/or the common voltage line VSL may each include a second pattern portion DPP on a same virtual line (e.g., a virtual straight line in the first direction) as the first patter portion PP of the first vertical voltage line VVIL. A width (e.g., a width in the first direction) of the second pattern portion DPP of any one of the vertical conductive lines VCL may be greater than a width (e.g., a width in the first direction) of another portion of the corresponding vertical conductive line VCL.

In an embodiment, while the first pattern portion PP is a structure for electrical contact through the first contact hole CNT1 right under the first pattern portion PP, the second pattern portion DPP, which is not used for electrical contact, may be considered as a kind of dummy pattern portion in terms of electrical contact. In other words, a contact hole for electrical contact is not provided right under the second pattern portion DPP. According to the embodiment shown in FIG. 10, as at least one of the vertical conductive lines further comprises the second pattern portion DPP, the decrease in the resolution and/in the quality of image of the display device may be prevented according to differences between structures such as presence or absence of a pattern portion.

In an embodiment, the second pattern portion DPP may be arranged at a side (e.g., on a virtual line XL described above on a plane) with reference to the virtual line XL extending in the first direction (e.g., the ±x direction) to cross the first capacitor Cst and the second capacitor Chold provided in each of the subpixel circuits PC. For example, the second pattern portion DPP may be at a position corresponding to a node N shown in FIG. 3.

In an embodiment, on a plane, with reference to the virtual line XL described above, the first horizontal voltage line HVIL may be opposite the 2-1 horizontal voltage line HVAL(G) and the 2-2 horizontal voltage line HVAL(RB). For example, the first horizontal voltage line HVIL may be arranged above the virtual line XL, and the 2-1 horizontal voltage line HVAL(G) and the 2-2 horizontal voltage line HVAL(RB) may be arranged under the virtual line XL.

According to some embodiments, a display device which may operate at a high rate without decrease in the resolution may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims. The embodiments disclosed in the present disclosure and illustrated in the drawings are provided as particular examples for more easily explaining the technical contents according to the present disclosure and helping understand the embodiments of the invention, but not intended to limit the scope of the embodiments of the invention. Accordingly, the scope of the various embodiments of the invention should be interpreted to include, in addition to the embodiments disclosed herein, all alterations or modifications derived from the technical ideas of the various embodiments of the invention. Moreover, the embodiments or parts of the embodiments may be combined in whole or in part without departing from the scope of the invention.

What is claimed is:

1. A display device comprising:
a first subpixel circuit and a second subpixel circuit being disposed adjacent to each other in a first direction, the first subpixel circuit and the second subpixel circuit each comprising a driving transistor and a first capacitor;
a first light-emitting diode electrically connected to the first subpixel circuit;
a second light-emitting diode electrically connected to the second subpixel circuit;
a first horizontal voltage line extending in the first direction and electrically connected to a semiconductor layer of a first transistor electrically connected to the driving transistor of the first subpixel circuit;
a second horizontal voltage line extending in the first direction and electrically connected to a semiconductor layer of a second transistor electrically connected to the driving transistor of the second subpixel circuit; and
a first signal line extending in the first direction and electrically connected to each of a gate electrode of the first transistor of the first subpixel circuit and a gate electrode of the second transistor of the second subpixel circuit,
wherein the first horizontal voltage line and the second horizontal voltage line are disposed on different layers.

2. The display device of claim 1, further comprising:
an insulating layer interposed between the first horizontal voltage line and the second horizontal voltage line,
wherein the first horizontal voltage line is disposed under the insulating layer, and the second horizontal voltage line is disposed over the insulating layer.

3. The display device of claim 1, wherein:
each of the first subpixel circuit and the second subpixel circuit further comprises a second capacitor,
the first capacitor comprises a first lower electrode disposed on a same layer as a gate electrode of the driving transistor and a first upper electrode disposed over the first lower electrode,
the second capacitor comprises a second lower electrode disposed on a same layer as the first upper electrode and a second upper electrode disposed over the second lower electrode, and
the first horizontal voltage line is disposed on a same layer as the second upper electrode.

4. The display device of claim 3, wherein:
the second lower electrode is disposed on a same layer as the first upper electrode, and
the first lower electrode is disposed on a same layer as the gate electrode of the driving transistor.

5. The display device of claim 1, wherein the first horizontal voltage line is electrically connected to the semiconductor layer of the first transistor through a bridge electrode.

6. The display device of claim 5, wherein the bridge electrode is disposed on a same layer as the second horizontal voltage line.

7. The display device of claim 1, wherein the first signal line comprises:
a first sub-signal line; and
a second sub-signal line disposed on the first sub-signal line and electrically connected to the first sub-signal line.

8. The display device of claim 7, wherein:
the second sub-signal line is disposed on a same layer as the second horizontal voltage line, and
the first sub-signal line comprises each of the gate electrode of the first transistor of the first subpixel circuit and the gate electrode of the second transistor of the second subpixel circuit.

9. The display device of claim 1, wherein:
the first transistor of the first subpixel circuit electrically connects the first horizontal voltage line to a subpixel electrode of the first light-emitting diode, in response to a signal from the first signal line, and
the second transistor of the second subpixel circuit electrically connects the second horizontal voltage line to a subpixel electrode of the second light-emitting diode, in response to a signal from the first signal line.

10. The display device of claim 1, further comprising:
a plurality of vertical voltage lines extending in a second direction crossing the first direction,
wherein the plurality of vertical voltage lines are disposed apart from one another and a plurality of subpixel circuits are arranged between two adjacent vertical voltage lines.

11. The display device of claim 10, further comprising:
a third horizontal voltage line extending in the first direction,
wherein a portion of a first vertical voltage line of the plurality of vertical voltage lines comprises a first pattern portion having a width greater than a width of another portion of the first vertical voltage line and is electrically connected to the third horizontal voltage line through a contact hole which is disposed directly under the first pattern portion, and
a portion of a second vertical voltage line of the plurality of vertical voltage lines comprises a second pattern portion having a width greater than a width of another portion of the second vertical voltage line and a contact hole which is not located directly under the second pattern portion.

12. The display device of claim 11, wherein:
the first horizontal voltage line and the second horizontal voltage line are disposed adjacent to each other, and
with reference to a virtual line extending in the first direction to cross the first capacitor in a plan view, the third horizontal voltage line is disposed opposite to the first horizontal voltage line and the second horizontal voltage line.

13. A display device comprising:
a first subpixel circuit and a second subpixel circuit disposed adjacent to each other in a first direction, the first subpixel circuit and the second subpixel circuit each comprising a driving transistor and a first capacitor;
a first light-emitting diode electrically connected to the first subpixel circuit;
a second light-emitting diode electrically connected to the second subpixel circuit;
a first horizontal voltage line extending in the first direction and electrically connected to a semiconductor layer of a first transistor electrically connected to the driving transistor of the first subpixel circuit;
a first vertical voltage line extending in a second direction crossing the first direction and electrically connected to the first horizontal voltage line;
a second horizontal voltage line extending in the first direction and electrically connected to a semiconductor layer of a second transistor electrically connected to the driving transistor of the second subpixel circuit;
a second vertical voltage line extending in the second direction and electrically connected to the second horizontal voltage line; and
a first signal line extending in the first direction and electrically connected to each of a gate electrode of the first transistor and a gate electrode of the second transistor.

14. The display device of claim 13, wherein a plurality of subpixel circuits are arranged between the first vertical voltage line and the second vertical voltage line.

15. The display device of claim 13, further comprising:
a third horizontal voltage line extending in the first direction; and
a third vertical voltage line extending in the second direction,
wherein a portion of the third vertical voltage line comprises a first pattern portion having a width greater than a width of another portion of the third vertical voltage line and the portion of the third vertical voltage line is electrically connected to the third horizontal voltage line through a contact hole which is disposed directly under the first pattern portion, and
a portion of at least one selected from among the first vertical voltage line and the second vertical voltage line comprises a second pattern portion having a width greater than a width of another portion of the at least one selected from among the first vertical voltage line and the second vertical voltage line and a contact hole which is not directly located under the second pattern portion.

16. The display device of claim 13, wherein:
each of the first subpixel circuit and the second subpixel circuit further comprises a second capacitor,
the first capacitor comprises a first lower electrode disposed on a same layer as a gate electrode of the driving transistor and a first upper electrode disposed over the first lower electrode,
the second capacitor comprises a second lower electrode disposed on a same layer as the first upper electrode and a second upper electrode disposed over the second lower electrode, and
the first horizontal voltage line is disposed on a same layer as the second upper electrode and the second horizontal voltage line is disposed on a layer which is different from a layer on which the first horizontal voltage line is disposed.

17. The display device of claim 13, wherein the first horizontal voltage line is electrically connected to a semiconductor layer of the first transistor through a bridge electrode.

18. The display device of claim 17, wherein the bridge electrode is disposed on a same layer as the second horizontal voltage line.

19. The display device of claim 13, wherein the first signal line comprises:
a first sub-signal line; and
a second sub-signal line disposed on the first sub-signal line and electrically connected to the first sub-signal line.

20. The display device of claim 19, wherein:
the second sub-signal line is disposed on a same layer as the second horizontal voltage line, and
the first sub-signal line comprises each of the gate electrode of the first transistor and the gate electrode of the second transistor.
